(19) United States
(12) Patent Application Publication
(10) Pub. No.: US 2026/0271269 A1
(43) Pub. Date: Sep. 10, 2026

(54) CONDUCTIVE STACK AND SEMICONDUCTOR DEVICE INCLUDING THE SAME

(71) Applicant: Samsung Electronics Co., Ltd., Suwon-si (KR)

(72) Inventors: Seung Wan Yoo, Suwon-si (KR); Taek Jung Kim, Suwon-si (KR); Myung Kyu Lee, Suwon-si (KR); Hyung-Seok Hong, Suwon-si (KR); Ah Young Kim, Suwon-si (KR)

(73) Assignee: Samsung Electronics Co., Ltd., Suwon-si (KR)

(21) Appl. No.: 19/559,100

(22) Filed: Mar. 6, 2026

(30) Foreign Application Priority Data
Mar. 10, 2025 (KR) 10-2025-0030908

(51) Int. Cl. H10B 12/00; H10D 64/23

(52) U.S. Cl. CPC H10B 12/315; H10D 64/251

(57) ABSTRACT

There is provided a conductive stack with reduced electrical resistance. The conductive stack includes a lower conductive layer, a barrier conductive layer on the lower conductive layer, an insertion layer on the barrier conductive layer, including a silicide nitride of a first metal element, a first upper conductive layer on the insertion layer, including the first metal element and a second upper conductive layer on the first upper conductive layer, including a second metal element different from the first metal element.

### CROSS-REFERENCE TO RELATED APPLICATIONS

This present application claims priority to and the benefit under 35 U.S.C. § 119(a)-(d) of Korean Patent Application No. 10-2025-0030908, filed on Mar. 10, 2025, in the Korean Intellectual Property Office, the entire disclosure of which is incorporated herein by reference.

### FIELD

The present disclosure relates to a conductive stack and a semiconductor device including the same.

### BACKGROUND

As semiconductor devices become more highly integrated, tungsten (W) and molybdenum (Mo) are being researched as materials used for wiring of the semiconductor devices. In addition, when a high fusion point metal such as tungsten (W) and molybdenum (Mo) is used as the wiring, a barrier conductive layer for preventing the diffusion of metal elements may be used together. However, there is a problem that the barrier conductive layer is damaged and the electrical resistance of the wiring increases in the process of depositing tungsten (W) and molybdenum (Mo) onto the barrier conductive layer by a physical vapor deposition (PVD) process or the like.

### SUMMARY

According to aspects of the present disclosure, there is provided a conductive stack comprising a lower conductive layer, a barrier conductive layer on the lower conductive layer, an insertion layer on the barrier conductive layer, including a silicide nitride of a first metal element, a first upper conductive layer on the insertion layer, including the first metal element and a second upper conductive layer on the first upper conductive layer, including a second metal element different from the first metal element.

According to aspects of the present disclosure, there is provided a conductive stack comprising a lower conductive layer including polysilicon, a barrier conductive layer on the lower conductive layer, including titanium (ti), an insertion layer on the barrier conductive layer, including tungsten silicide nitride (WSiN), a first upper conductive layer on the insertion layer, including tungsten (W) and a second upper conductive layer on the first upper conductive layer, including molybdenum (Mo).

According to aspects of the present disclosure, there is provided a semiconductor memory device comprising, an active pattern, a bit line connected to a first portion of the active pattern, a capacitor structure connected to a second portion of the active pattern and a word line which intersects the active pattern between the first portion and the second portion, wherein the bit line includes a lower conductive layer connected to the active pattern, a barrier conductive layer on the lower conductive layer, an insertion layer on the barrier conductive layer, including tungsten silicide nitride (WSiN), a first upper conductive layer on the insertion layer, including tungsten (W), and a second upper conductive layer on the first upper conductive layer, including molybdenum (Mo).

### BRIEF DESCRIPTION OF THE DRAWINGS

The above and other aspects and features of the present disclosure will become more apparent by describing in detail embodiments thereof with reference to the attached drawings, in which:

FIG. 1 is a cross-sectional view for explaining the conductive stack according to some embodiments.

FIG. 2 is a graph showing a penetration depth of tungsten ions according to ion energy in the conductive stack according to some embodiments.

FIGS. 3A, 3B and 3C are graphs showing a change in characteristics depending on a nitrogen concentration of an insertion layer in the conductive stack according to some embodiments.

FIG. 4 is a cross-sectional view for explaining a conductive stack according to some embodiments.

FIGS. 5A and 5B are graphs for explaining a change in characteristics depending on the nitrogen concentration of the insertion layer in a conductive stack according to some embodiments.

FIG. 6 is a layout diagram for explaining a semiconductor device according to some embodiments.

FIG. 7 is a cross-sectional view taken along line A-A of FIG. 6.

FIGS. 8 and 9 are various enlarged views for explaining a region R1 of FIG. 7.

FIG. 10 is a cross-sectional view taken along a line B-B of FIG. 6.

FIG. 11 is a layout diagram for explaining a semiconductor device according to some embodiments.

FIG. 12 is a cross-sectional view taken along C-C of FIG. 11.

FIGS. 13 and 14 are various enlarged views for explaining a region R2 of FIG. 12.

FIG. 15 is a cross-sectional view taken along D-D of FIG. 11.

### DETAILED DESCRIPTION

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

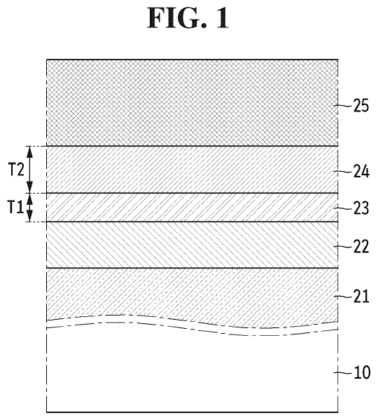

Hereinafter, a conductive stack according to example embodiments will be described referring to FIGS. 1 to 5B.

Aspects of the present disclosure provide a conductive stack with reduced electrical resistance.

Aspects of the present disclosure also provide a semiconductor device including a conductive stack with reduced electrical resistance.

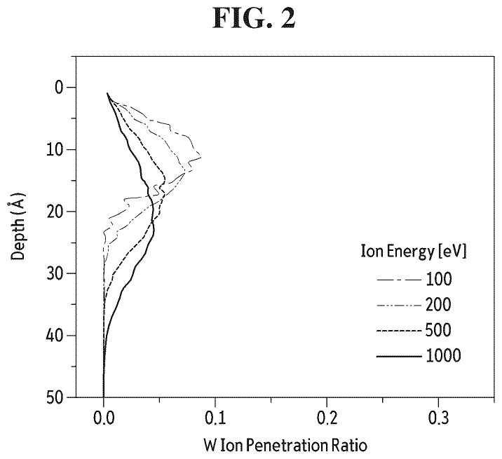

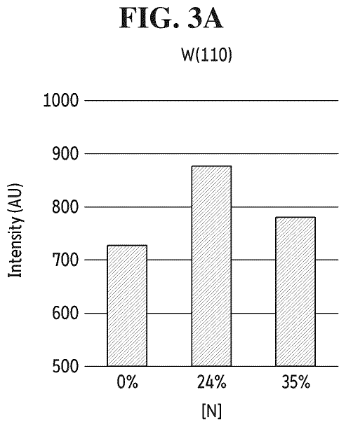

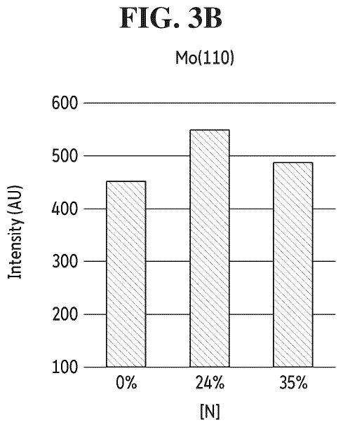

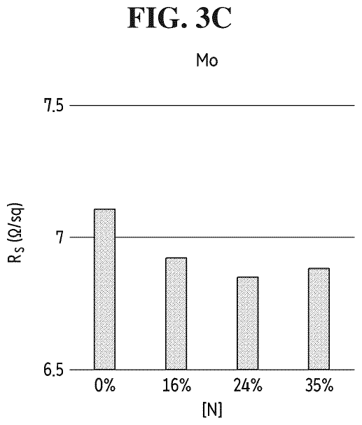

FIG. 1 is a cross-sectional view for explaining the conductive stack according to some embodiments. FIG. 2 is a graph showing a penetration depth of tungsten ions according to ion energy in the conductive stack according to some embodiments. FIGS. 3A to 3C are graphs showing a change in characteristics depending on a nitrogen concentration of an insertion layer in the conductive stack according to some embodiments.

Referring to FIGS. 1 to 3C, the conductive stack according to some embodiments includes a lower conductive layer 21, a barrier conductive layer 22, an insertion layer 23, a first upper conductive layer 24, and a second upper conductive layer 25, which are stacked sequentially on a first substrate 10.

The first substrate 10 may be a semiconductor substrate such as a silicon wafer. The first substrate 10 may be, but is not limited to, a structure in which a base substrate and an epitaxial layer are stacked. The first substrate 10 may be a silicon substrate, a gallium arsenide substrate, a silicon germanium substrate, and an SOI (Semiconductor On Insulator) substrate. As an example, the first substrate 10 will be described as a silicon substrate below.

The lower conductive layer 21 may be formed on the first substrate 10. The lower conductive layer 21 may be in direct contact with the first substrate 10 or may be spaced apart from the first substrate 10. The lower conductive layer 21 may include, a conductive material, for example, but is not limited to, a metal such as tungsten (W), molybdenum (Mo), ruthenium (Ru), cobalt (Co) and nickel (Ni), or a semiconductor material such as silicon.

In some embodiments, the lower conductive layer 21 may include polysilicon (poly-Si). As an example, the lower conductive layer 21 may be a polysilicon film doped with n-type impurities (e.g., P, Sb, or As) and/or p-type impurities (e.g., boron (B), indium (In), gallium (Ga), or aluminum (Al)).

The barrier conductive layer 22 may be formed on the lower conductive layer 21. For example, the barrier conductive layer 22 may be stacked directly on the lower conductive layer 21, and be in contact with the lower conductive layer 21. The barrier conductive layer 22 may be interposed between the lower conductive layer 21 and the insertion layer 23. The barrier conductive layer 22 may include a metal or metal nitride for preventing a metal element (hereinafter, a first metal element) included in the insertion layer 23 and/or the first upper conductive layer 24 from diffusing into the lower conductive layer 21. For example, the barrier conductive layer 22 may include, but is not limited to, at least one of titanium (Ti), tantalum (Ta), tungsten (W), nickel (Ni), cobalt (Co), platinum (Pt), an alloy thereof or a nitride thereof.

In some embodiments, the barrier conductive layer 22 may include titanium (Ti). For example, the barrier conductive layer 22 may include at least one of a titanium film (Ti), a titanium nitride film (TiN), a titanium silicide nitride film (TiSiN) or a combination thereof.

The insertion layer 23 may be formed on the barrier conductive layer 22. For example, the insertion layer 23 may be stacked directly on the barrier conductive layer 22, and be in contact with the barrier conductive layer 22. The insertion layer 23 may be interposed between the barrier conductive layer 22 and the first upper conductive layer 24. The insertion layer 23 may include a silicide nitride of the first metal element. The first metal element may be, for example, but is not limited to, one of aluminum (Al), copper (Cu), tungsten (W), molybdenum (Mo), cobalt (Co), and ruthenium (Ru).

In some embodiments, the first metal element may be tungsten (W). That is, the insertion layer 23 may include tungsten silicide nitride (WSiN).

In some embodiments, a ratio of silicon atoms to metal atoms in the silicide nitride of the insertion layer 23 may be about 0.5 or more, about 1.0 or more, or about 1.5 or more, and may be about 3.0 or less, about 4.0 or less, or about 5.0 or less. As an example, when the insertion layer 23 is a tungsten silicide nitride film (WSiN), the ratio of silicon (Si) atoms to tungsten (W) atoms may be about 0.5 to about 3.0.

The first upper conductive layer 24 may be formed on the insertion layer 23. For example, the first upper conductive layer 24 may be stacked directly on the insertion layer 23, and be in contact with the insertion layer 23. The first upper conductive layer 24 may be interposed between the insertion layer 23 and the second upper conductive layer 25. The first upper conductive layer 24 may include a first metal element. For example, the first upper conductive layer 24 may include, but is not limited to, one of aluminum (Al), copper (Cu), tungsten (W), molybdenum (Mo), cobalt (Co) and ruthenium (Ru). As an example, when the insertion layer 23 is a tungsten silicide nitride film (WSiN), the first upper conductive layer 24 may be a tungsten film (W).

In some embodiments, the tungsten film (W) of the first upper conductive layer 24 may include a {110} crystal plane.

The second upper conductive layer 25 may be formed on the first upper conductive layer 24. For example, the second upper conductive layer 25 may be stacked directly on the first upper conductive layer 24, and be in contact with the first upper conductive layer 24. The second upper conductive layer 25 may include a second metal element different from the first metal element. The second metal element may be, for example, but is not limited to, one of aluminum (Al), copper (Cu), tungsten (W), molybdenum (Mo), cobalt (Co) and ruthenium (Ru). The first upper conductive layer 24 may be provided as an incubation layer for forming the second upper conductive layer 25.

In some embodiments, the electrical conductivity of the second metal element may be greater than the electrical conductivity of the first metal element. As an example, the first metal element may be tungsten (W) and the second metal element may be molybdenum (Mo).

In some embodiments, a grain size of the first upper conductive layer 24 may be greater than a grain size of the second upper conductive layer 25. In such a case, the grain size of the second upper conductive layer 25 increases relative to a single layer of the second upper conductive layer 25 to which the first upper conductive layer 24 is not provided, and the electrical resistance of the second upper conductive layer 25 may decrease. As an example, when the first upper conductive layer 24 is a tungsten film (W), the second upper conductive layer 25 may be a molybdenum film (Mo).

In some embodiments, the molybdenum film (Mo) of the second upper conductive layer 25 may include a {110} crystal plane.

In some embodiments, a thickness T1 of the insertion layer 23 may be about 25 Å or more. For example, the thickness T1 of the insertion layer 23 may be about 25 Å to about 100 Å, about 30 Å to about 100 Å, about 35 Å to about 100 Å, or about 40 Å to about 100 Å. In the above range, the insertion layer 23 may prevent damage to the barrier conductive layer 22 due to penetration of the first metal element (e.g., tungsten (W)) in the deposition process of the first upper conductive layer 24 and/or the second upper conductive layer 25.

For example, FIG. 2 shows measurement of a penetration depth of tungsten ions (W ions) penetrating into a tungsten silicide nitride film (WSiN), in a process in which a tungsten film (W) is formed as the first upper conductive layer 24 on the tungsten silicide nitride film (WSiN) as the insertion layer 23, using a physical vapor deposition (PVD) process. As shown in FIG. 2, when the ion energy is 100 eV (or 200 eV, or 500 eV or 1000 eV), the penetration depth of most tungsten ions (W ions) may be about 25 Å or less (or about 30 Å or less, or about 35 Å or less, or about 40 Å or less). Therefore, it may be confirmed that when the thickness of the insertion layer 23 is about 25 Å or more (or about 30 Å or more, or about 35 Å or more, or about 40 Å or more), damage to the barrier conductive layer 22 due to the penetration of tungsten ions may be effectively prevented.

In some embodiments, the nitrogen concentration in the silicide nitride of the insertion layer 23 may be about 20 atomic % or more and less than about 35 atomic %. In the above range, the orientation of the first upper conductive layer 24 and/or the orientation of the second upper conductive layer 25 are improved, and the electrical resistance of the first upper conductive layer 24 and/or the electrical resistance of the second upper conductive layer 25 may decrease.

For example, in FIG. 3A, an x-axis represents the nitrogen concentration of the tungsten silicide nitride film (WSiN) as the insertion layer 23, and a y-axis represents an XRD (X-ray diffraction) peak intensity (XRD peak intensity) corresponding to the (110) crystal plane of the tungsten film (W) as the first upper conductive layer 24. As shown in FIG. 3A, when the nitrogen concentration of the insertion layer 23 (tungsten silicide nitride film (WSiN)) is about 24 atomic %, it may be confirmed that the orientation of the first upper conductive layer 24 (tungsten film (W)) is improved, compared to a case where the nitrogen concentration is about 0 atomic % (for example, when no nitrogen is included) or a case where the nitrogen concentration is about 35 atomic %.

For example, in FIG. 3B, an x-axis represents the nitrogen concentration of the tungsten silicide nitride film (WSiN) as the insertion layer 23, and a y-axis represents the XRD (X-ray diffraction) peak intensity (XRD peak intensity) corresponding to the (110) crystal plane of the molybdenum film (Mo) as the second upper conductive layer 25. As shown in FIG. 3B, when the nitrogen concentration of the insertion layer 23 (tungsten silicide nitride film (WSiN)) is about 24 atomic %, it may be confirmed that the orientation of the second upper conductive layer 25 (molybdenum film (Mo)) is improved, compared to a case where the nitrogen concentration is about 0 atomic % (e.g., when no nitrogen is included) or a case where the nitrogen concentration is about 35 atomic %.

In FIG. 3C, an x-axis represents the nitrogen concentration of the tungsten silicide nitride film (WSiN) as the insertion layer 23, and a y-axis represents a sheet resistance of the molybdenum film (Mo) as the second upper conductive layer 25. Thus, as shown in FIG. 3C, when the nitrogen concentration of the insertion layer 23 (tungsten silicide nitride film (WSiN)) is about 24 atomic %, it may be confirmed that the second upper conductive layer 25 (molybdenum film (Mo)) has a reduced sheet resistance.

In some embodiments, a thickness T2 of the first upper conductive layer 24 may be about 10 Å to about 200 Å or less. In the above range, the first upper conductive layer 24 may be provided as an incubation layer for forming the second upper conductive layer 25.

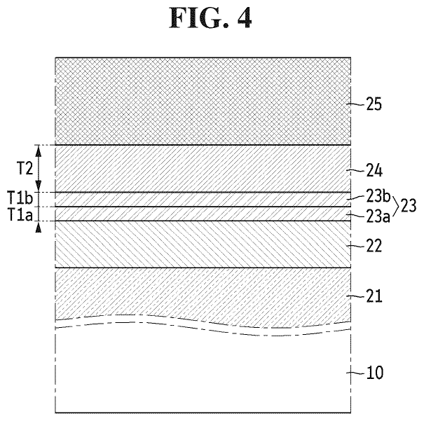

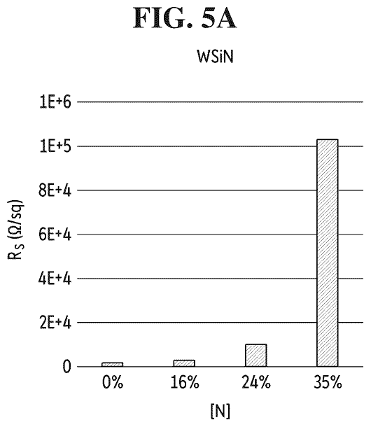

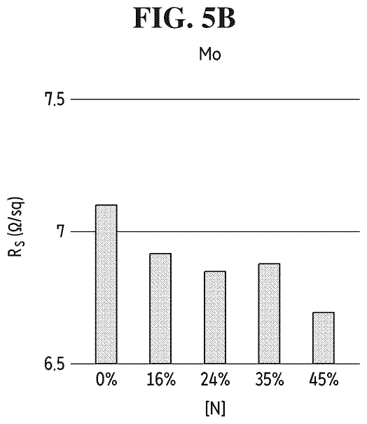

FIG. 4 is a cross-sectional view for explaining a conductive stack according to some embodiments. FIGS. 5A and 5B are graphs for explaining a change in characteristics depending on the nitrogen concentration of the insertion layer in a conductive stack according to some embodiments. For convenience of explanation, repeated parts of contents explained above using FIGS. 1 to 3C will be briefly explained or omitted.

Referring to FIGS. 4 to 5B, in the conductive stack according to some embodiments, the insertion layer 23 includes a first sub-insertion layer 23a and a second sub-insertion layer 23b.

The first sub-insertion layer 23a and the second sub-insertion layer 23b may be stacked sequentially on the barrier conductive layer 22. For example, the first sub-insertion layer 23a may be stacked directly on the barrier conductive layer 22, and be in contact with the barrier conductive layer 22. The first sub-insertion layer 23a may be interposed between the barrier conductive layer 22 and the second sub-insertion layer 23b. For example, the first upper conductive layer 24 may be stacked directly on the second sub-insertion layer 23b, and be in contact with the in contact with the second sub-insertion layer 23b. The second sub-insertion layer 23b may be interposed between the first sub-insertion layer 23a and the first upper conductive layer 24.

Each of the first sub-insertion layer 23a and the second sub-insertion layer 23b may include a nitride silicide of a first metal element. As an example, each of the first sub-insertion layer 23a and the second sub-insertion layer 23b may include tungsten silicide nitride (WSiN).

The first sub-insertion layer 23a and the second sub-insertion layer 23b may have different nitrogen concentrations from each other. In some embodiments, the nitrogen concentration of the first sub-insertion layer 23a may be smaller than the nitrogen concentration of the second sub-insertion layer 23b.

In some embodiments, the nitrogen concentration of the first sub-insertion layer 23a may be less than about 35 atomic %. For example, the nitrogen concentration of the first sub-Attorney insertion layer 23a may be equal to or greater than about 0 atomic % and less than about 35 atomic %, between about 0 atomic % and about 30 atomic %, between about 0 atomic % and about 20 atomic %, or between about 0 atomic % and about 10 atomic %. Preferably, the nitrogen concentration of the first sub-insertion layer 23a may be equal to or less than about 24 atomic %. Or, the first sub-insertion layer 23a may not include nitrogen. In the above range, the first sub-insertion layer 23a may provide a reduced electrical resistance.

For example, in FIG. 5A, an x-axis represents the nitrogen concentration of the tungsten silicide nitride film (WSiN) as the first sub-insertion layer 23a, and a y-axis represents the sheet resistance of the tungsten silicide nitride film (WSiN) as the first sub-insertion layer 23a. As shown in FIG. 5A, when the nitrogen concentration of the first sub-insertion layer 23a (tungsten silicide nitride film (WSiN)) is less than 35 atomic %, it may be confirmed that the first sub-insertion layer 23a has a reduced sheet resistance.

In some embodiments, the nitrogen concentration of the second sub-insertion layer 23b may be about 40 atomic % to about 65 atomic %, or about 43 atomic % to about 65 atomic %. Preferably, the nitrogen concentration of the second sub-insertion layer 23b may be about 45 atomic % to about 65 atomic %. In the above range, the orientation of the first upper conductive layer 24 and/or the orientation of the second upper conductive layer 25 are improved, and the electrical resistance of the first upper conductive layer 24 and/or the electrical resistance of the second upper conductive layer 25 may decrease.

For example, in FIG. 5B, an x-axis represents the nitrogen concentration of the tungsten silicide nitride film (WSiN) as the second sub-insertion layer 23b, and a y-axis represents the sheet resistance of the molybdenum film (Mo) as the second upper conductive layer 25. As shown in FIG. 5B, when the nitrogen concentration of the second sub-insertion layer 23b (tungsten silicide nitride film (WSiN)) is 45 atomic % or more, it may be confirmed that the second upper conductive layer 25 (molybdenum film (Mo)) has a reduced sheet resistance.

Although FIG. 4 only shows that a thickness T1a of the first sub-insertion layer 23a and a thickness T1b of the second sub-insertion layer 23b are equal to each other, this is merely an example. It goes without saying that the thickness T1a of the first sub-insertion layer 23a and the thickness T1b of the second sub-insertion layer 23b may be different from each other, unlike the shown example.

As the semiconductor devices become more highly integrated, tungsten (W) and molybdenum (Mo) are being researched as materials used for wiring of the semiconductor devices. In addition, when high fusion point metals such as tungsten (W) and molybdenum (Mo) are used as the wiring, a barrier conductive layer for preventing diffusion of metal elements may be used together. However, there is a problem that the barrier conductive layer is damaged in the process of depositing tungsten (W) and molybdenum (Mo) onto the barrier conductive layer by a physical vapor deposition (PVD) process or the like, and the electrical resistance of the wiring increases.

The conductive stack according to some embodiments may provide reduced electrical resistance by using the insertion layer 23. Specifically, as described above, the insertion layer 23 is interposed between the barrier conductive layer 22 and the first upper conductive layer 24, and may prevent damage to the barrier conductive layer 22 caused by the penetration of the first metal element (e.g., tungsten (W)) in the process of deposition of the first upper conductive layer 24 and/or the second upper conductive layer 25. Furthermore, as described above, the insertion layer 23 may reduce the sheet resistance of the second upper conductive layer 25, by improving the orientation of the first upper conductive layer 24 and/or the orientation of the second upper conductive layer 25. This makes it possible to provide a conductive stack with reduced electrical resistance.

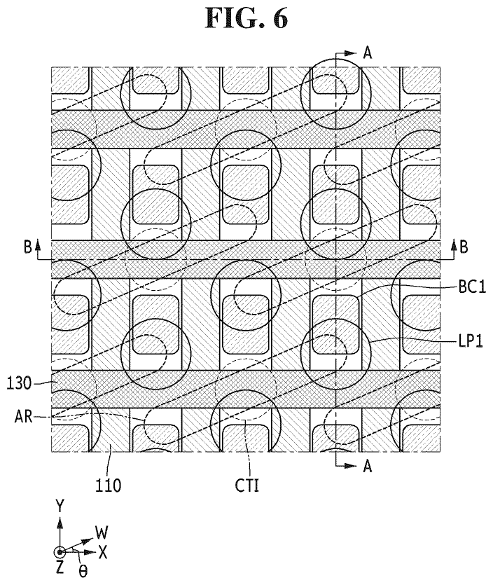

Hereinafter, a semiconductor device according to the example embodiments will be described referring to FIGS. 1 to 15. In FIGS. 6 to 15, a DRAM (Dynamic Random-Access Memory) will be mainly described as an example of a semiconductor device, but this is merely an example. Those skilled in the art will understand that the technical idea of the present disclosure is also applicable to various other semiconductor devices including a conductive stack, for example, a system LSI (large scale integration), a flash memory, a SRAM, an EEPROM, a PRAM, a MRAM or a RERAM, an image sensor such as a CIS (CMOS imaging sensor), a MEMS (micro-electro-mechanical system), an active element, a passive element, or the like.

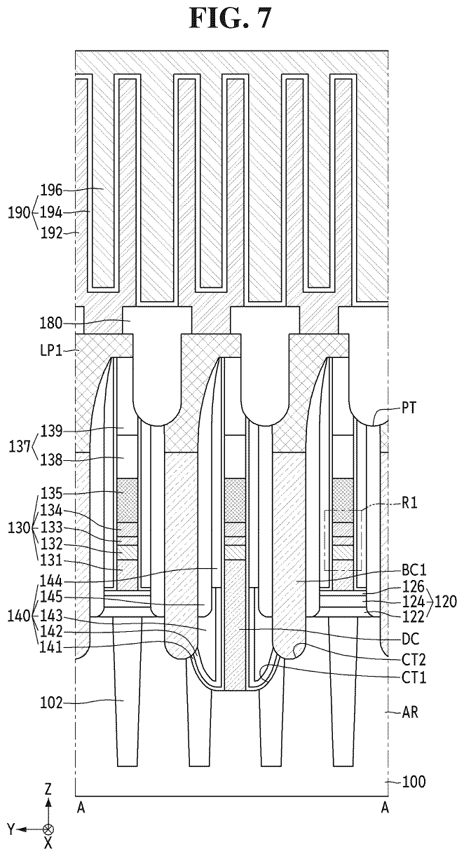

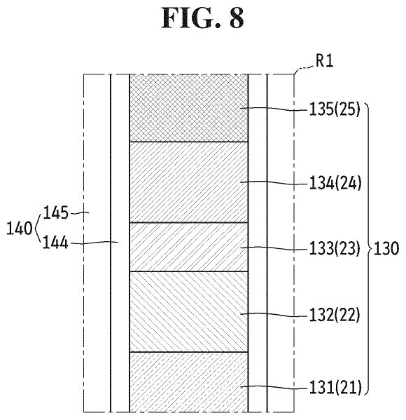

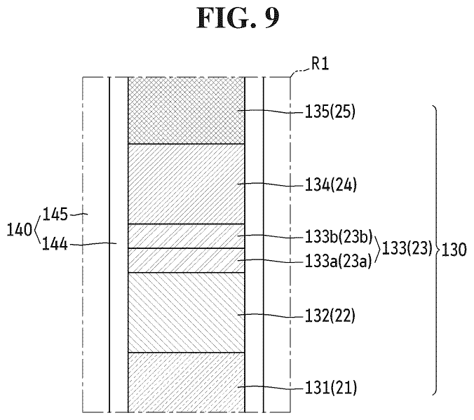

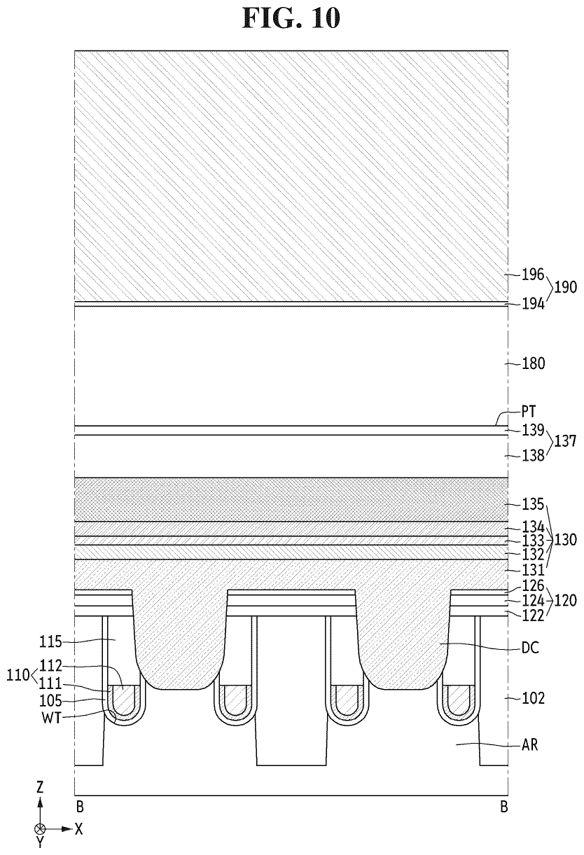

FIG. 6 is a layout diagram for explaining a semiconductor device according to some embodiments. FIG. 7 is a cross-sectional view taken along line A-A of FIG. 6. FIGS. 8 and 9 are various enlarged views for explaining a region R1 of FIG. 7. FIG. 10 is a cross-sectional view taken along a line B-B of FIG. 6. For convenience of explanation, repeated parts of those explained above using FIGS. 1 to 5B will be briefly explained or omitted.

Referring to FIGS. 6 to 10, the semiconductor device according to some embodiments includes a second substrate 100, an element isolation pattern 102, a first gate dielectric film 105, a first gate electrode 110, a first capping pattern 115, a base insulating film 120, a first conductive pattern 130, a second capping pattern 137, a direct contact DC, a spacer structure 140, a first contact pattern BC1, a first landing pad LP1, and a first data storage structure 190.

The second substrate 100 may be similar to the first substrate 10 described above using FIG. 1, and therefore the detailed description will not be provided below.

The second substrate 100 may include a plurality of first active patterns AR. The plurality of first active patterns AR may be defined by the element isolation pattern 102 inside the second substrate 100. As the design rule of semiconductor memory devices decreases, each first active pattern AR may be formed in the form of a diagonal bar. For example, as shown in FIG. 6, each first active pattern AR may be in the form of a bar extending in a third direction W different from the first direction X and the second direction Y in a plane in which the first direction X and the second direction Y extend.

The first active patterns AR may be in the form of a plurality of bars extending in parallel directions to each other. In some embodiments, the center of one of the first active patterns AR may be disposed to be adjacent to an end of the other of the first active patterns AR.

Each first active pattern AR may include a first portion (e.g., a central portion) and a second portion (e.g., both ends) that are different from each other. Each of the first and second portions may be provided as a source/drain region including an impurity. In some embodiments, the first portion (e.g., the central portion) may be connected to the first conductive pattern 130 through a direct contact DC, and the second portion (e.g., both ends) may be connected to the first data storage structure 190 through the first contact pattern BC1 and/or the first landing pad LP1.

The first gate electrode 110 may be formed on the second substrate 100 and the element isolation pattern 102. The first gate electrode 110 may intersect the first active pattern AR and the first conductive pattern 130. For example, the first gate electrode 110 may extend long in a second direction Y parallel to an upper side of the second substrate 100, diagonally intersect the first active pattern AR, and vertically intersect the first conductive pattern 130. The plurality of first gate electrodes 110 may be spaced apart from each other and arranged along the first direction X.

The first gate electrode 110 may intersect the first active pattern AR between the direct contact DC and the first contact pattern BC1. For example, the first gate electrode 110 may intersect a region of the first active patterns AR interposed between the first portion (e.g., the central portion) of the first active pattern AR and the second portion (e.g., both ends) of the first active pattern AR. The first gate electrode 110 may be provided as a word line of the semiconductor memory device according to some embodiments.

The first gate electrode 110 may be a single film, but may be a multi-layer film as shown in FIG. 10. For example, the first gate electrode 110 may include a first electrode layer 111 and a second electrode layer 112 that are stacked sequentially on the second substrate 100 and the element isolation pattern 102. Each of the first electrode layer 111 and the second electrode layer 112 may include, for example, but are not limited to, at least one of a metal, a polysilicon or a combination thereof. As an example, the first electrode layer 111 may include titanium nitride (TiN), and the second electrode layer 112 may include polysilicon doped with n-type impurities.

The first gate dielectric film 105 may be interposed between the first gate electrode 110 and the second substrate 100 (or the first active patterns AR). The first gate dielectric film 105 may include, but is not limited to, at least one of silicon oxide, silicon oxynitride, silicon nitride, and a high-dielectric constant material having a higher dielectric constant than silicon oxide.

The first capping pattern 115 may be formed on the first gate electrode 110. The first capping pattern 115 may extend along the upper side of the first gate electrode 110. The first capping pattern 115 may include an insulating material, for example, but is not limited to, at least one of silicon oxide, silicon nitride, silicon oxynitride, silicon oxycarbonitride or a combination thereof. The first capping pattern 115 may be a single film or a multi-layer film made of a combination of several types of insulating materials.

In some embodiments, the first gate electrode 110 may be buried in the second substrate 100. For example, the second substrate 100 and the element isolation pattern 102 may include a gate trench WT that extends long in the second direction Y. The first gate dielectric film 105 may extend along the profile of the gate trench WT. The first gate electrode 110 may fill a part of the gate trench WT on the first gate dielectric film 105. The first capping pattern 115 may fill another part of the gate trench WT on the first gate electrode 110. In this case, the upper side of the first gate electrode 110 may be formed to be lower than the upper side of the second substrate 100.

The base insulating film 120 may be formed on the second substrate 100 and the element isolation pattern 102. The base insulating film 120 may be interposed between the second substrate 100 and the first conductive pattern 130, and between the element isolation pattern 102 and the first conductive pattern 130.

The base insulating film 120 may be a single film, but may be a multi-layer film as shown in FIGS. 7 and 10. For example, the base insulating film 120 may include a first insulating film 122, a second insulating film 124, and a third insulating film 126 that are stacked sequentially on the second substrate 100 and the element isolation pattern 102. As an example, the first insulating film 122 may include a silicon oxide film, the second insulating film 124 may include a silicon nitride film, and the third insulating film 126 may include a silicon oxide film.

The first conductive pattern 130 may be formed on the second substrate 100, the element isolation pattern 102, and the base insulating film 120. The first conductive pattern 130 may intersect the first active patterns AR and the first gate electrode 110. For example, the first conductive pattern 130 may extend long in the first direction X, diagonally intersect the first active pattern AR, and vertically intersect the first gate electrode 110. The plurality of first conductive patterns 130 may be spaced apart from each other, and arranged along the second direction Y. The first conductive pattern 130 may be provided as a bit line of the semiconductor memory device according to some embodiments.

The first conductive pattern 130 may be a conductive stack formed by stacking a plurality of conductive layers. For example, the first conductive pattern 130 may include a first conductive layer 131, a second conductive layer 132, a third conductive layer 133, a fourth conductive layer 134, and a fifth conductive layer 135 that are stacked sequentially on the first active patterns AR and/or the base insulating film 120.

In some embodiments, the conductive stack of FIG. 1 may be provided as the first conductive pattern 130. For example, as shown in FIG. 8, each of the first conductive layer 131, the second conductive layer 132, the third conductive layer 133, the fourth conductive layer 134, and the fifth conductive layer 135 may correspond to the lower conductive layer 21, the barrier conductive layer 22, the insertion layer 23, the first upper conductive layer 24, and the second upper conductive layer 25 of FIG. 1. As an example, the first conductive layer 131 may include a polysilicon film (poly-Si), the second conductive layer 132 may include titanium (Ti), the third conductive layer 133 may include a tungsten silicide nitride film (WSiN), the fourth conductive layer 134 may include a tungsten film (W), and the fifth conductive layer 135 may include a molybdenum film (Mo).

In some embodiments, as shown in FIG. 9, the third conductive layer 133 may include a first sub-conductive layer 133a and a second sub-conductive layer 133b. The first sub-conductive layer 133a and the second sub-conductive layer 133b may have different nitrogen concentrations from each other. For example, each of the first sub-conductive layer 133a and the second sub-conductive layer 133b may correspond to the first sub-insertion layer 23a and the second sub-insertion layer 23b of FIG. 1.

The second capping pattern 137 may be formed on the first conductive pattern 130. The second capping pattern 137 may extend along the upper side of the first conductive pattern 130. The second capping pattern 137 may be a single film, but may be a multi-layer film as shown. For example, the second capping pattern 137 may include a first capping layer 138 and a second capping layer 139 that are stacked sequentially on the first conductive pattern 130. Each of the first capping layer 138 and the second capping layer 139 may include an insulating material, for example, but are not limited to, at least one of silicon oxide, silicon nitride, silicon oxynitride, silicon oxycarbonitride, or a combination thereof. As an example, each of the first capping layer 138 and the second capping layer 139 may include silicon nitride.

A direct contact DC may be formed on the first active pattern AR. The direct contact DC may connect the first active patterns AR and the first conductive pattern 130. For example, the second substrate 100 may include a first contact trench CT1 that penetrates the base insulating film 120 to expose the first portion (e.g., the central portion) of the first active pattern AR. The direct contact DC may be formed in the first contact trench CT1 and electrically connect the first portion (e.g., the central portion) of the first active patterns AR to the first conductive pattern 130. In some embodiments, the first conductive layer 131 of the first conductive pattern 130 may be connected to the first portion (e.g., the central portion) of the first active pattern AR through the direct contact DC.

The direct contact (DC) may include a conductive material, for example, but is not limited to, at least one of polysilicon, TiN, TiSiN, tungsten, tungsten silicide or a combination thereof. In some embodiments, the direct contact DC may be formed at the same level as the first conductive layer 131. In this specification, “the same level” means formation by the same fabricating process. For example, the first conductive layer 131 and the direct contact DC may have the same material composition.

The spacer structure 140 may be formed on the side face of the first conductive pattern 130. The spacer structure 140 may extend along the side face of the first conductive pattern 130 and the side face of the second capping pattern 137.

The spacer structure 140 may include an insulating material, for example, but is not limited to, at least one of silicon oxide, silicon nitride, silicon oxynitride, silicon oxycarbonitride or a combination thereof.

In some embodiments, the spacer structure 140 may be a multi-layer film consisting of a combination of several types of insulating materials. For example, the spacer structure 140 may include a base spacer 141, a first buried spacer 142, a second buried spacer 143, a first side spacer 144, and a second side spacer 145.

The base spacer 141 may be formed on the side face of the first conductive pattern 130. For example, the base spacer 141 may extend conformally along the profiles of at least a part of the side face of the first conductive pattern 130 and the side face of the second capping pattern 137.

The first buried spacer 142 may be formed on the base spacer 141 inside the first contact trench CT1. For example, the first buried spacer 142 may extend conformally along the profile of the base spacer 141 inside the first contact trench CT1.

The second buried spacer 143 may be formed on the first buried spacer 142 inside the first contact trench CT1. For example, the second buried spacer 143 may fill the region of the first contact trench CT1 that remains after the base spacer 141 and the first buried spacer 142 are formed.

The first side spacer 144 may be formed on the outer side of the base spacer 141. The first side spacer 144 may also be formed on the first buried spacer 142 and the second buried spacer 143. For example, the first side spacer 144 may extend conformally along the profiles of a part of the side face of the second capping pattern 137 and the side face of the first conductive pattern 130.

The second side spacer 145 may be formed on the outer side of the first side spacer 144. The first side spacer 144 may also be formed on the second buried spacer 143. For example, the second side spacer 145 may extend conformally along the profiles of a part of the side face of the second capping pattern 137 and the side face of the first conductive pattern 130.

The first contact pattern BC1 may be formed on the second substrate 100, the element isolation pattern 102, and the spacer structure 140. The first contact pattern BC1 may be spaced apart from the first conductive pattern 130, and connected to the first active patterns AR. For example, the second substrate 100 may include a second contact trench CT2 that penetrates the base insulating film 120 to expose the second portion (e.g., both ends) of the first active pattern AR. The first contact pattern BC1 may be formed inside the second contact trench CT2, and be connected to the second portion (e.g., both ends) of the first active pattern AR.

The first contact pattern BC1 may be formed on the side face of the first conductive pattern 130. The first contact pattern BC1 may be spaced apart from the first conductive pattern 130 by the spacer structure 140. For example, as shown in FIG. 7, the first contact pattern BC1 may extend along a part of an outer side of the spacer structure 140. In some embodiments, the upper side of the first contact pattern BC1 may be formed to be lower than the upper side of the second capping pattern 137.

The first contact pattern BC1 may form a plurality of isolated regions spaced apart from each other. For example, as shown in FIG. 6, the plurality of first contact patterns BC1 may be interposed between the plurality of first conductive patterns 130 and between the plurality of first gate electrodes 110 in a plan view. In some embodiments, the plurality of first contact patterns BC1 may be arranged in a lattice structure.

The first contact pattern BC1 may include a conductive material, for example, but is not limited to, at least one of polysilicon, TiN, TiSiN, tungsten, tungsten silicide or a combination thereof. As an example, the first contact pattern BC1 may include polysilicon.

The first landing pad LP1 may be formed on the first contact pattern BC1. The first landing pad LP1 may be connected to the first contact pattern BC1. In some embodiments, the first landing pad LP1 may be disposed to overlap at least a part of the first contact pattern BC1 in a fourth direction Z that intersects the upper side of the second substrate 100. For example, a part of the first landing pad LP1 may overlap the first contact pattern BC1, and another part of the first landing pad LP1 may overlap a part of the spacer structure 140 and a part of the second capping pattern 137.

The first landing pad LP1 may include a conductive material, for example, but is not limited to, at least one of polysilicon, TiN, TiSiN, tungsten, tungsten silicide or a combination thereof. As an example, the first landing pad LP1 may include tungsten (W).

The first landing pad LP1 may form a plurality of isolated regions spaced apart from each other. For example, a pad trench PT that defines a plurality of first landing pads LP1 may be formed. The pad trench PT may extend from the upper side of the first landing pad LP1, and may be formed such that its lower side is lower than the upper side of the spacer structure 140. Furthermore, at least a part of the pad trench PT may be disposed to overlap at least a part of the spacer structure 140. For example, the pad trench PT may overlap a part of the spacer structure 140 and a part of the second capping pattern 137. Accordingly, the plurality of first landing pads LP1 may be separated from each other by the pad trench PT.

In some embodiments, an isolation pattern 180 that fills the pad trench PT may be formed. The isolation pattern 180 may include an insulating material, for example, but is not limited to, at least one of silicon oxide, silicon oxynitride, silicon nitride, and a low-k material having a dielectric constant smaller than that of silicon oxide. The plurality of first landing pads LP1 may be electrically separated from each other by the isolation pattern 180.

In some embodiments, the plurality of first landing pads LP1 may be arranged in a honeycomb structure. The first landing pads LP1 arranged in the honeycomb structure may further improve the degree of integration of the semiconductor memory device.

The first data storage structure 190 may be formed on the isolation pattern 180 and the first landing pad LP1. The first data storage structure 190 may be connected to an upper side of the first landing pad LP1. For example, the isolation pattern 180 may be patterned to expose at least a part of an upper side of the first landing pad LP1. The first data storage structure 190 may be connected to at least a part of the upper side of the first landing pad LP1 exposed by the isolation pattern 180. The first data storage structure 190 may electrically connect the first contact pattern BC1 and the first landing pad LP1 to the second portion (e.g., both ends) of the first active pattern AR.

The first data storage structure 190 is controlled by the first gate electrode 110 provided as the word line and the first conductive pattern 130 provided as the bit line, and may store data.

In some embodiments, the first data storage structure 190 may include a first lower electrode 192, a first capacitor dielectric film 194, and a first upper electrode 196 that are stacked sequentially on the first landing pad LP1. The first data storage structure 190 may store charges in the first capacitor dielectric film 194, using a potential difference generated between the first lower electrode 192 and the first upper electrode 196.

Each of the first lower electrode 192 and the first upper electrode 196 may include, for example, but are not limited to, a doped polysilicon, a metal or a metal nitride. In addition, the first capacitor dielectric film 194 may include, for example, but are not limited to, a silicon oxide or a high-k material having a dielectric constant larger than that of the silicon oxide.

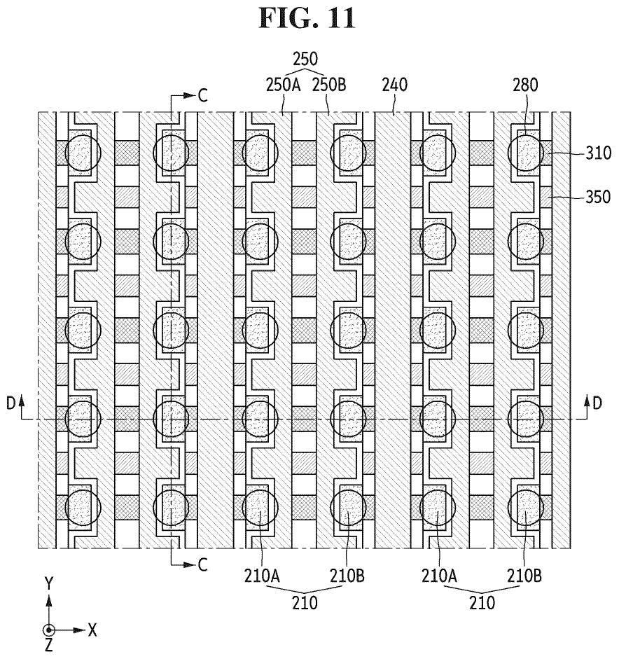

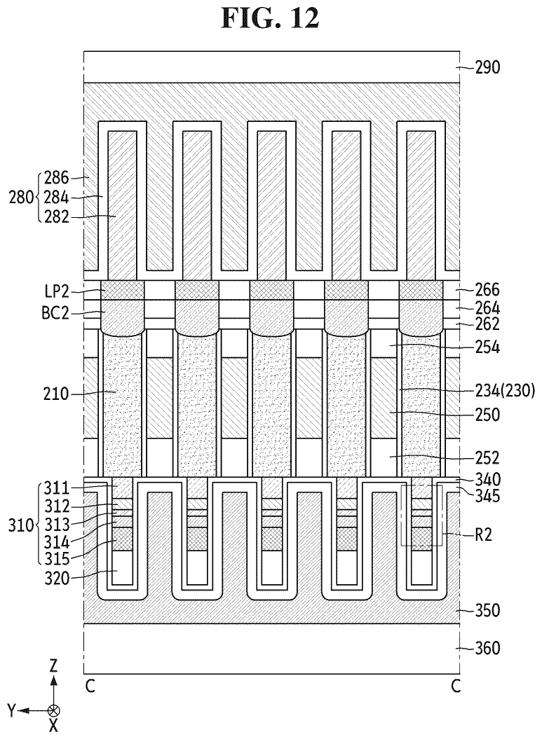

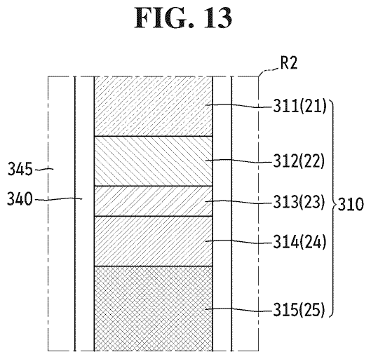

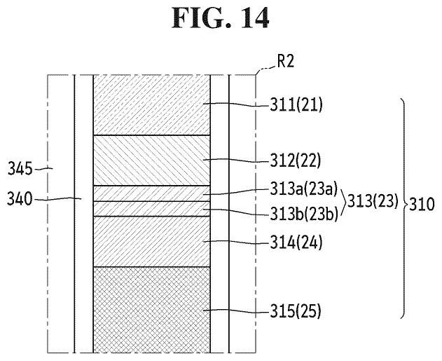

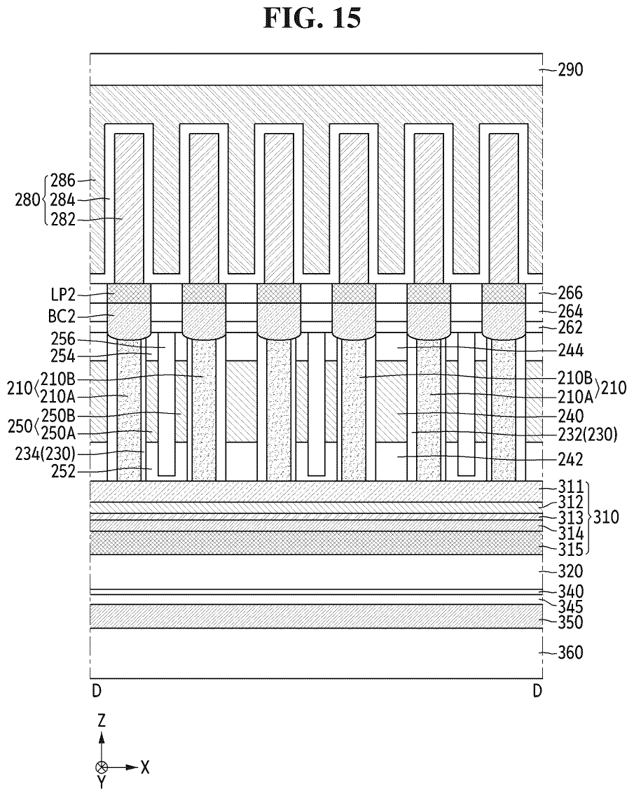

FIG. 11 is a layout diagram for explaining a semiconductor device according to some embodiments. FIG. 12 is a cross-sectional view taken along C-C of FIG. 11. FIGS. 13 and 14 are various enlarged views for explaining a region R2 of FIG. 12. FIG. 15 is a cross-sectional view taken along D-D of FIG. 11. For convenience of explanation, repeated parts of the contents explained above using FIGS. 1 to 5B will be briefly explained or omitted.

Referring to FIGS. 11 to 15, a semiconductor device according to some embodiments includes a plurality of second active patterns 210, a second gate dielectric film 230, a back gate electrode 240, a second gate electrode 250, a second contact pattern BC2, a second landing pad LP2, a second data memory structure 280, an upper insulating film 290, a second conductive pattern 310, a third capping pattern 320, a liner film 340, a spacer film 345, a shield conductive film 350, and a lower insulating film 360.

The plurality of second active patterns 210 may be arranged two-dimensionally along a horizontal plane. For example, the second active patterns 210 may be arranged in a matrix shape along the first direction X and the second direction Y that intersect each other.

Each second active pattern 210 may extend in a vertical direction. For example, each second active pattern 210 may extend long in a fourth direction Z that intersects the first direction X and the second direction Y. A height of each second active pattern 210 extending in the fourth direction Z may be greater than widths of each second active pattern 210 (e.g., a width in the first direction X and/or a width in the second direction Y). The heights of each second active pattern 210 may be, but are not limited to, about two to about ten times the widths of each second active pattern 210. Each second active pattern 210 may be provided as a channel region of a vertical channel transistor VCT. The vertical channel transistor may refer to a structure in which the channel length of a channel layer extends in a vertical direction (e.g., the fourth direction Z).

In some embodiments, the plurality of second active patterns 210 may include a first column 210A and a second column 210B. Each of the first column 210A and the second column 210B may include a column of second active patterns 210 arranged along the second direction Y. The first columns 210A and the second columns 210B may be arranged alternately along the first direction X.

Each of the second active patterns 210 may include a semiconductor material. For example, each of the second active patterns 210 may include elemental semiconductor materials such as monocrystalline silicon (monocrystalline Si), polycrystalline silicon (polycrystalline Si), amorphous silicon (amorphous Si), silicon germanium (SiGe), SGOI (silicon germanium on insulator), indium antimonide, lead telluride, indium arsenide, indium phosphide, gallium arsenide or gallium antimonide. Alternatively, for example, each of the second active patterns 210 may include a metal oxide semiconductor material, such as IGZO (indium gallium zinc oxide) or ITZO (indium tin zinc oxide).

Each of the second active patterns 210 may include a single layer or multiple layers of the semiconductor material. In some embodiments, each of the second active patterns 210 may include a single crystal semiconductor material. As an example, each of the second active patterns 210 may include monocrystalline silicon.

Each of the second active patterns 210 may include a third portion (e.g., a lower portion) and fourth portion (e.g., an upper portion) that are different from each other. In some embodiments, the third portion (e.g., the lower portion) may be connected to the second conductive pattern 310, and the fourth portion (e.g., the upper portion) may be connected to the second data storage structure 280 through the second contact pattern BC2 and/or the second landing pad LP2.

The second gate dielectric film 230 may surround the side faces of each second active pattern 210. In some embodiments, the second gate dielectric film 230 may include a first dielectric film 232 and a second dielectric film 234. Each of the first dielectric film 232 and the second dielectric film 234 may extend long in the second direction Y. The first dielectric film 232 may be interposed between the second active patterns 210 and the back gate electrodes 240. The second dielectric film 234 may be interposed between the second active patterns 210 and the second gate electrode 250. Each of the first dielectric film 232 and the second dielectric film 234 may include, for example, but is not limited to, at least one of silicon oxide, silicon oxynitride, and a high dielectric (high-k) constant material having a higher dielectric constant than silicon oxide, or a combination thereof.

The second gate electrode 250 may be formed on the side faces of each second active pattern 210. The second gate electrode 250 is spaced apart from each second active pattern 210 by the second dielectric film 234.

The second gate electrode 250 may intersect each second active pattern 210. For example, the second gate electrode 250 may extend long in the second direction Y. The plurality of second gate electrodes 250 may be spaced apart from each other in the first direction X and extend side by side (or parallel) in the second direction Y. The second gate electrode 250 may be provided as a word line of the semiconductor memory device according to some embodiments.

The second gate electrode 250 may include a conductive material, for example, at least one of doped polysilicon, a metal, a conductive metal nitride, a conductive metal silicide, a conductive metal oxide or a combination thereof. For example, the second gate electrode 250 may include, but is not limited to, at leat one of doped polysilicon, Al, Cu, Ti, Ta, Ru, W, Mo, Pt, Ni, Co, TiN, TaN, WN, NbN, TiAl, TiAIN, TiSi, TiSIN, TaSi, TaSIN, RuTIN, NiSi, CoSi, IrOₓ, RuOₓ, or combinations thereof.

In some embodiments, the lower side of the second gate electrode 250 may be formed to be higher than the lower side of each second active pattern 210. For example, as shown in FIG. 12, a first lower spacer 252 may be formed on the lower side of the second gate electrode 250. The second gate electrode 250 may be spaced apart from the second conductive pattern 310 in the fourth direction Z by the first lower spacer 252.

In some embodiments, the upper side of the second gate electrode 250 may be formed to be lower than the upper side of each of the second active patterns 210. For example, as shown in FIG. 12, a first upper spacer 254 may be formed on the upper side of the second gate electrode 250. The second gate electrode 250 may be spaced apart from the second contact pattern BC2 and/or the etching stop film 262 in the fourth direction Z by the first upper spacer 254.

Each of the first lower spacer 252 and the first upper spacer 254 may include an insulating material, for example, but is not limited to, at least one of silicon oxide, silicon nitride, silicon oxynitride, silicon oxycarbonitride or a combination thereof. Each of the first lower spacer 252 and the first upper spacer 254 may be a single film made of one type of insulating material, or may be a multi-layer film made of a combination of several types of insulating materials.

In some embodiments, the second gate electrode 250 may include a first sub-gate electrode 250A and a second sub-gate electrode 250B. The first sub-gate electrode 250A may intersect each second active pattern 210 of the first column 210A, and the second sub-gate electrode 250B may intersect each second active pattern 210 of the second column 210B. For example, the first sub-gate electrode 250A may be disposed on a side face of the first column 210A opposite to the second column 210B, and the second sub-gate electrode 250B may be disposed on the side face of the second column 210B opposite to the first column 210A.

The first sub-gate electrode 250A and the second sub-gate electrode 250B may be spaced apart from each other in the first direction X. For example, as shown in FIG. 15, an isolation spacer 256 may be formed between the first sub-gate electrode 250A and the second sub-gate electrode 250B. The isolation spacer 256 may extend long in the second direction Y to separate the first sub-gate electrode 250A and the second sub-gate electrode 250B in the first direction X.

The back gate electrode 240 may be disposed on the side faces of each second active pattern 210. The back gate electrode 240 may be spaced apart from each second active pattern 210 by the first dielectric film 232.

The back gate electrode 240 may intersect each second active pattern 210. For example, the back gate electrode 240 may extend long in the second direction Y. The plurality of back gate electrodes 240 may be spaced apart from each other in the first direction X, and extend side by side (or parallel) in the second direction Y.

The back gate electrode 240 may include a conductive material, for example, at least one of a doped polysilicon, a metal, a conductive metal nitride, a conductive metal silicide, a conductive metal oxide or a combination thereof. For example, the back gate electrode 240 may include, for example, but is not limited to, at least one of doped polysilicon, Al, Cu, Ti, Ta, Ru, W, Mo, Pt, Ni, Co, TiN, TaN, WN, NbN, TiAl, TiAIN, TiSi, TiSIN, TaSi, TaSIN, RuTiN, NiSi, CoSi, IrOₓ, RuOₓ or combinations thereof.

In some embodiments, the lower side of the back gate electrode 240 may be formed to be higher than the lower sides of the respective second active patterns 210. For example, as shown in FIG. 15, a second lower spacer 242 may be formed on the lower side of the back gate electrode 240. The back gate electrode 240 may be spaced apart from the second conductive pattern 310 in the fourth direction Z by the second lower spacer 242.

In some embodiments, the upper side of the back gate electrode 240 may be formed to be lower than the upper sides of the respective second active patterns 210. For example, as shown in FIG. 15, a second upper spacer 244 may be formed on the upper side of the back gate electrode 240. The back gate electrode 240 may be spaced apart from the second contact pattern BC2 and/or the etching stop film 262 in the fourth direction Z by the second upper spacer 244.

Each of the second lower spacer 242 and the second upper spacer 244 may include an insulating material, for example, but is not limited to, at least one of silicon oxide, silicon nitride, silicon oxynitride, silicon oxycarbonitride or a combination thereof. Each of the second lower spacer 242 and the second upper spacer 244 may be a single film made of one type of insulating material, or may be a multi-layer film made of a combination of several types of insulating materials.

In some embodiments, the first column 210A and the second column 210B may share one back gate electrode 240. For example, the first column 210A may be disposed on one side face of the back gate electrode 240, and the second column 210B may be disposed on the other side face of the back gate electrode 240.

The second contact pattern BC2 may be connected to the fourth portion (e.g., the upper portion) of each second active pattern 210. For example, the second contact pattern BC2 may be formed on the upper sides of each second active pattern 210. For example, an etching stop film 262 and a first interlayer insulating film 264 may be stacked sequentially on the second active pattern 210. The second contact pattern BC2 may penetrate each of the etching stop film 262 and the first interlayer insulating film 264, and be in contact with the upper sides of each second active pattern 210.

The second contact pattern BC2 may include a conductive material, for example, but is not limited to, at least one of a doped polysilicon, a conductive metal nitride, a conductive metal silicon nitride, a metal carbonitride, a conductive metal silicide, a conductive metal oxide, a two-dimensional material, a metal, or a combination thereof.

The second landing pad LP2 may be formed on the upper side of the second contact pattern BC2. The second landing pad LP2 may be connected to the second contact pattern BC2. For example, the second interlayer insulating film 266 may be stacked on the upper side of the first interlayer insulating film 264. The second landing pad LP2 may penetrate the second interlayer insulating film 266, and be in contact with the upper side of the second contact pattern BC2.

The second landing pad LP2 may include a conductive material, for example, but is not limited to, at least one of a doped polysilicon, a conductive metal nitride, a conductive metal silicon nitride, a metal carbonitride, a conductive metal silicide, a conductive metal oxide, a two-dimensional material, a metal or a combination thereof.

The second data storage structure 280 may be formed on the upper side of the second landing pad LP2 and the upper side of the second interlayer insulating film 266. The second data storage structure 280 may be connected to the second landing pad LP2. The second data storage structure 280 may be electrically connected to the fourth portion (e.g., the upper portion) of the second active pattern 210 through the second contact pattern BC2 and the second landing pad LP2.

The second data storage structure 280 may be controlled by the second gate electrode 250 provided as the word line and the second conductive pattern 310 provided as the bit line, and store data.

In some embodiments, the second data storage structure 280 may include a second lower electrode 282, a second capacitor dielectric film 284, and a second upper electrode 286 that are stacked sequentially on the second landing pad LP2. The second data storage structure 280 may store charges inside the second capacitor dielectric film 284, using a potential difference generated between the second lower electrode 282 and the second upper electrode 286.

Each of the second lower electrode 282 and the second upper electrode 286 may include, but are not limited to, a doped polysilicon, a metal or a metal nitride. The second capacitor dielectric film 284 may also include, but are not limited to, a silicon oxide or a high-k material having a dielectric constant greater than that of silicon oxide.

The upper insulating film 290 may be stacked on the second data storage structure 280. The upper insulating film 290 may cover at least a part of the second data storage structure 280. The upper insulating film 290 may include, for example, but are not limited to, at least one of silicon oxide, silicon nitride, silicon oxynitride, silicon oxycarbonitride or a combination thereof.

The second conductive pattern 310 may be formed on the lower sides of each second active pattern 210. The second conductive pattern 310 may be connected to the third portions (e.g., the lower portions) of each second active pattern 210. The second conductive pattern 310 may intersect the second gate electrode 250. For example, the second conductive pattern 310 may extend long in the first direction X. The plurality of second conductive patterns 310 may be spaced apart from each other in the second direction Y and extend side by side (or parallel) in the first direction X. Each second conductive pattern 310 may be commonly connected to a row of second active patterns 210 arranged along the first direction X. The second conductive pattern 310 may be provided as a bit line of the semiconductor memory device according to some embodiments.

The second conductive pattern 310 may be a conductive stack formed by stacking a plurality of conductive layers. For example, the second conductive pattern 310 may include a sixth conductive layer 311, a seventh conductive layer 312, an eighth conductive layer 313, a ninth conductive layer 314, and a tenth conductive layer 315 that are stacked sequentially on the lower sides of the second active patterns 210.

In some embodiments, the conductive stack of FIG. 1 may be provided as the second conductive pattern 310. For example, as shown in FIG. 13, each of the sixth conductive layer 311, the seventh conductive layer 312, the eighth conductive layer 313, the ninth conductive layer 314, and the tenth conductive layer 315 may correspond to the lower conductive layer 21, the barrier conductive layer 22, the insertion layer 23, the first upper conductive layer 24, and the second upper conductive layer 25 of FIG. 1. As an example, the sixth conductive layer 311 may include a polysilicon film (poly-Si), the seventh conductive layer 312 may include titanium (Ti), the eighth conductive layer 313 may include a tungsten silicide nitride film (WSiN), and the ninth conductive layer 315 may include a molybdenum film (Mo).

In some embodiments, the sixth conductive layer 311 of the second conductive pattern 310 may be in direct contact with the third portion (e.g., the lower portion) of the second active patterns 210.

In some embodiments, as shown in FIG. 14, the eighth conductive layer 313 may include a third sub-conductive layer 313a and a fourth sub-conductive layer 313b. The third sub-conductive layer 313a and the fourth sub-conductive layer 313b may have different nitrogen concentrations from each other. For example, each of the third sub-conductive layer 313a and the fourth sub-conductive layer 313b may correspond to the first sub-insertion layer 23a and the second sub-insertion layer 23b of FIG. 1.

The third capping pattern 320 may extend along the lower side of the second conductive pattern 310. The third capping pattern 320 may extend long in the first direction X. The third capping pattern 320 may include an insulating material, for example, but is not limited to, at least one of silicon oxide, silicon nitride, silicon oxynitride, silicon oxycarbonitride, and combinations thereof.

The liner film 340 may be stacked under the second conductive pattern 310 and the third capping pattern 320. For example, the liner film 340 may extend conformally along the profiles of the side face and lower side of the third capping pattern 320, the side face of the second conductive pattern 310, the lower side of the second gate dielectric film 230, the lower side of the first lower spacer 252, and the lower side of the second lower spacer 242.

The liner film 340 may include an insulating material, for example, but is not limited to, at least one of silicon oxide, silicon nitride, silicon oxynitride, silicon oxycarbonitride, and combinations thereof. As an example, the liner film 340 may include a silicon nitride film.

The spacer film 345 may be stacked under the liner film 340. For example, the spacer film 345 may extend conformally along the profile of the side face and lower side of the liner film 340.

The spacer film 345 may include an insulating material, for example, but is not limited to, at least one of silicon oxide, silicon nitride, silicon oxynitride, silicon oxycarbonitride, and combinations thereof. As an example, the spacer film 345 may include a silicon oxide film.

The shield conductive film 350 may be stacked under the spacer film 345. At least a part of the shield conductive film 350 may be interposed between the second conductive patterns 310 arranged along the second direction Y. For example, as shown in FIG. 12, the shield conductive film 350 may be formed to fill at least a part of the region between one second conductive pattern 310 and the other second conductive pattern 310. The shield conductive film 350 may be spaced apart from the second conductive pattern 310 by the liner film 340 and/or the spacer film 345.

The shield conductive film 350 may include a conductive material, for example, at least one of a doped polysilicon, a metal, a conductive metal nitride, a conductive metal silicide, a conductive metal oxide or a combination thereof. The shield conductive film 350 may reduce a coupling noise between the second conductive patterns 310 in the second direction Y. For example, a predetermined bias voltage (for example, a ground voltage) may be applied to the shield conductive film 350.

The lower insulating film 360 may be stacked under the shield conductive film 350. The lower insulating film 360 may cover at least a part of the shield conductive film 350. The lower insulating film 360 may include, for example, but is not limited to, at least one of silicon oxide, silicon nitride, silicon oxynitride, silicon oxycarbonitride, or a combination thereof.

According to embodiments, there is provided a method of manufacturing a conductive stack comprising providing a lower conductive layer, providing a barrier conductive layer on the lower conductive layer, providing an insertion layer on the barrier conductive layer, including a silicide nitride of a first metal element, providing a first upper conductive layer on the insertion layer, including the first metal element and a providing second upper conductive layer on the first upper conductive layer, including a second metal element different from the first metal element.

According to embodiments, there is provided a method of manufacturing a semiconductor memory device comprising providing an active pattern, providing a bit line connected to a first portion of the active pattern, providing a capacitor structure connected to a second portion of the active pattern and a providing word line which intersects the active pattern between the first portion and the second portion, wherein the bit line includes a lower conductive layer connected to the active pattern, a barrier conductive layer on the lower conductive layer, an insertion layer on the barrier conductive layer, including tungsten silicide nitride (WSiN), a first upper conductive layer on the insertion layer, including tungsten (W), and a second upper conductive layer on the first upper conductive layer, including molybdenum (Mo).

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

What is claimed is:

1. A conductive stack comprising:
a lower conductive layer;
a barrier conductive layer on the lower conductive layer;
an insertion layer on the barrier conductive layer, including a silicide nitride of a first metal element;
a first upper conductive layer on the insertion layer, including the first metal element; and
a second upper conductive layer on the first upper conductive layer, including a second metal element different from the first metal element.

2. The conductive stack of claim 1,
wherein a thickness of the insertion layer is 25 Å to 100 Å.

3. The conductive stack of claim 1,
wherein a nitrogen concentration of the silicide nitride is 20 atomic % or more and less than 35 atomic %.

4. The conductive stack of claim 1,
wherein a ratio of silicon atoms to metal atoms in the silicide nitride is 0.5 to 3.0.

5. The conductive stack of claim 1, wherein:
an electrical conductivity of the second metal element is greater than an electrical conductivity of the first metal element, and
a grain size of the first upper conductive layer is greater than a grain size of the second upper conductive layer.

6. The conductive stack of claim 5, wherein:
the first metal element is tungsten (W), and
the second metal element is molybdenum (Mo).

7. The conductive stack of claim 1, wherein:
the insertion layer includes a first sub-insertion layer and a second sub-insertion layer that are stacked sequentially on the barrier conductive layer, and
a nitrogen concentration of the first sub-insertion layer is smaller than a nitrogen concentration of the second sub-insertion layer.

8. The conductive stack of claim 7, wherein:
the nitrogen concentration of the first sub-insertion layer is less than 35 atomic %, and the nitrogen concentration of the second sub-insertion layer is 45 atomic % to 65 atomic %.

9. The conductive stack of claim 1,
wherein the lower conductive layer includes polysilicon (poly-Si).

10. The conductive stack of claim 1,
wherein the barrier conductive layer includes titanium (Ti).

11. The conductive stack of claim 1,
wherein a thickness of the first upper conductive layer is 10 Å to 200 Å.

12. The conductive stack of claim 1,
wherein tungsten of the first upper conductive layer includes a {110} crystal plane.

13. The conductive stack of claim 1,
wherein molybdenum of the second upper conductive layer includes a {110} crystal plane.

14. A conductive stack comprising:
a lower conductive layer including polysilicon;
a barrier conductive layer on the lower conductive layer, including titanium (Ti);
an insertion layer on the barrier conductive layer, including tungsten silicide nitride (WSiN);
a first upper conductive layer on the insertion layer, including tungsten (W); and
a second upper conductive layer on the first upper conductive layer, including molybdenum (Mo).

15. The conductive stack of claim 14, wherein:
a thickness of the insertion layer is 25 Å to 100 Å, and
a nitrogen concentration of the tungsten silicide nitride is 20 atomic % or more and less than 35 atomic %.

16. The conductive stack of claim 14, wherein:
the insertion layer includes a first sub-insertion layer and a second sub-insertion layer that are stacked sequentially on the barrier conductive layer,
the nitrogen concentration of the first sub-insertion layer is 24 atomic % or less, and the nitrogen concentration of the second sub-insertion layer is 45 atomic % to 65 atomic %.

17. A semiconductor memory device comprising:
an active pattern;
a bit line connected to a first portion of the active pattern;
a capacitor structure connected to a second portion of the active pattern; and
a word line which intersects the active pattern between the first portion and the second portion,
wherein the bit line includes:
a lower conductive layer connected to the active pattern,
a barrier conductive layer on the lower conductive layer,
an insertion layer on the barrier conductive layer, including tungsten silicide nitride (WSIN),
a first upper conductive layer on the insertion layer, including tungsten (W), and
a second upper conductive layer on the first upper conductive layer, including molybdenum (Mo).

18. The semiconductor memory device of claim 17,
wherein a thickness of the insertion layer is 25 Å to 100 Å.

19. The semiconductor memory device of claim 17,
wherein a nitrogen concentration of the tungsten silicide nitride is 20 atomic % or more and less than 35 atomic %.

20. The semiconductor memory device of claim 17, wherein:
the insertion layer includes a first sub-insertion layer and a second sub-insertion layer that are stacked sequentially on the barrier conductive layer,
the nitrogen concentration of the first sub-insertion layer is 24 atomic % or less, and
the nitrogen concentration of the second sub-insertion layer is 45 atomic % to 65 atomic %.
